(19) United States
(12) Patent Application Publication
(10) Pub. No.: US 2008/0242117 A1
(43) Pub. Date: Oct. 2, 2008

(54) APPARATUS TO REDUCE WAFER EDGE TEMPERATURE AND BREAKAGE OF WAFERS

(76) Inventors: Panchapakesan Ramanarayanan, Sunnyvale, CA (US); Karson Knutson, Beaver, OR (US); Jack Hwang, Portland, OR (US); John Leonard, Portland, OR (US); Sridhar Govindaraju, Hillsboro, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/694,934

(22) Filed: Mar. 30, 2007

(51) Int. Cl. H01L 21/324

(52) U.S. Cl. 438/795; 257/E21.324

(57) ABSTRACT

In some embodiments radiation incident on a wafer is provided to perform an annealing process, and the wafer is cooled at an edge portion to reduce temperature and stress on the wafer. Other embodiments are described and claimed.

### TECHNICAL FIELD

The inventions generally relate to reduction of high temperature and breakage of wafers (for example, in an ultra-fast wafer anneal process).

### BACKGROUND

In microelectronics, a wafer is a thin slice of semiconducting material, such as a silicon crystal, upon which microcircuits are constructed by doping (for example, diffusion or ion implantation), chemical etching, and/or deposition of various materials. Wafers are made in various sizes, currently ranging, for example, from 1 inch (25.4 mm) to 11.8 inches (300 mm), and thicknesses, for example, of the order of 0.5 mm.

The trend in thermal processing that accompanies scaling the transistor sizes to smaller dimensions is to reduce the thermal cycle time combined with higher temperatures. For the modern process, this cycle time has been reduced to milliseconds with temperature jumps on the order of 100-1000 degrees Celsius. One of the main challenges of this technology is wafer breakage. The thermal stresses generated by heating the top surface of the entire wafer by up to approximately 1000C (1000 degrees Celsius) in approximately 1 msec produces tremendous stresses that can cause wafers to explode if there are defects in the incoming wafer. The most common failure is a wafer handling excursion on a process tool in an operation before the anneal step that results in edge damage. These excursions can result in thousands of affected wafers which need to be scrapped and can shut down an entire fab.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1A illustrates a graph according to some embodiments of the inventions.

FIG. 1B illustrates a wafer according to some embodiments of the inventions.

FIG. 2A illustrates a graph according to some embodiments of the inventions.

FIG. 2B illustrates a bar graph according to some embodiments of the inventions.

FIG. 3A illustrates an arrangement according to some embodiments of the inventions.

FIG. 3B illustrates a shadow ring according to some embodiments of the inventions.

FIG. 3C illustrates a shadow ring according to some embodiments of the inventions.

FIG. 4 illustrates a graph according to some embodiments of the inventions.

### DETAILED DESCRIPTION

Some embodiments of the inventions relate to reduction of high temperature and breakage of wafers.

In some embodiments radiation incident on a wafer is provided to perform an annealing process, and the wafer is cooled at an edge portion to reduce temperature and stress on the wafer (for example, in some embodiments stress occurring at the edge portion).

In some embodiments a wafer is fabricated according to a process of providing radiation incident on the wafer to perform an annealing process, and cooling the wafer at an edge portion to reduce temperature and stress on the wafer (for example, in some embodiments stress occurring at the edge portion).

In some embodiments a shadow ring includes an open center and a solid ring near an edge portion. The solid ring is to cool a wafer by blocking radiation provided during an annealing process of fabrication of the wafer so that stress of the wafer (for example, in some embodiments at an edge portion of the wafer) is reduced.

For the fabs that use the millisecond anneal process, one of the highest risks is wafer breakage during millisecond anneal (flash anneal). It has the potential to scrap thousands of wafers if there is an upstream wafer handling excursion. Current efforts include ensuring high quality wafer handling for all processing operations prior to flash anneal. Any mis-calibration of robotics that introduces chips or defects into the wafer edge can result in wafer shattering. The most common defect mode is edge damage from robotics. Typically, once the problem is identified, thousands of wafers may have been processed that are now at high risk for wafer breakage in the anneal tool.

In some embodiments the flash anneal module is made more insensitive to wafer edge defects from robot handling problems. The inventors have identified that the wafer edge contains the peak stress area on the wafer. According to some embodiments, addition of a blocking plate is very effective in reducing that stress.

In some embodiments a high temperature at an outer edge (and/or in some embodiments, at a corner) of a wafer may be reduced (for example, the existence of peak wafer stress at an outer portion of a wafer edge may be reduced). In some embodiments a high temperature and/or peak wafer stress occurring at an outer edge of a wafer in an outer 1 or 2 mm of the wafer, for example, may be significantly reduced. In some embodiments, a radiation blocking ring (for example, a shadow ring) may be inserted to significantly reduce wafer stress by reducing a size of the temperature rise at the outer region of a wafer. In some embodiments wafer shattering risk is significantly reduced. In some embodiments, a shadowing device and/or a cooling device lowers a temperature rise over an outer portion (for example, a last 3 mm) of a wafer edge. In some embodiments a risk of wafer breakage during a millisecond anneal (flash anneal) process is significantly reduced.

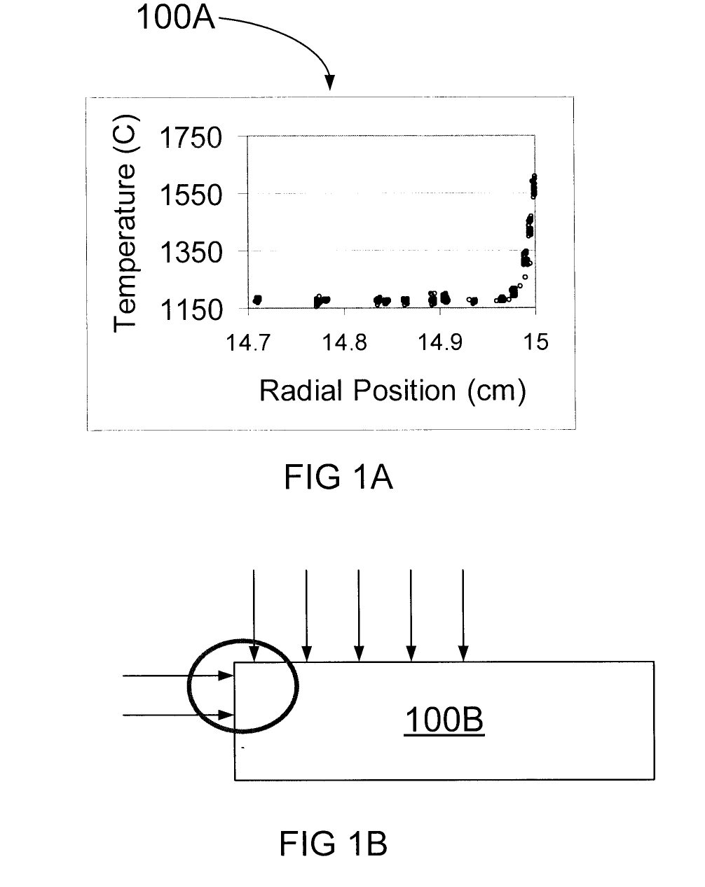

FIG. 1A illustrates a graph 100A according to some embodiments. FIG. 1A illustrates a temperature (in degrees Celsius) of various radial portions of a wafer during a flash anneal process of wafer fabrication. FIG. 1A illustrates a wafer that is 300 mm in diameter (150 mm in radius) but it is noted that other sizes of wafers larger and smaller than 300 mm may be used in some embodiments. As evident from FIG. 1A, the temperature during flash anneal is higher at outer radial positions of the wafer. FIG. 1B illustrates a wafer 100B according to some embodiments. As illustrated in FIG. 1B, wafer 100B receives radiation (radiation shown by arrows in FIG. 1B) incident on both top portions of the wafer and on edge portions of the wafer. This results in more energy and higher temperature in the wafer at the “corner” of the wafer due to extra radiation incident at the corner and/or edges of the wafer (the corner is shown generally by a circle at the corner of wafer 100B in FIG. 1B). This edge heating is a root cause for peak wafer stress occurring at the edge of the wafer.

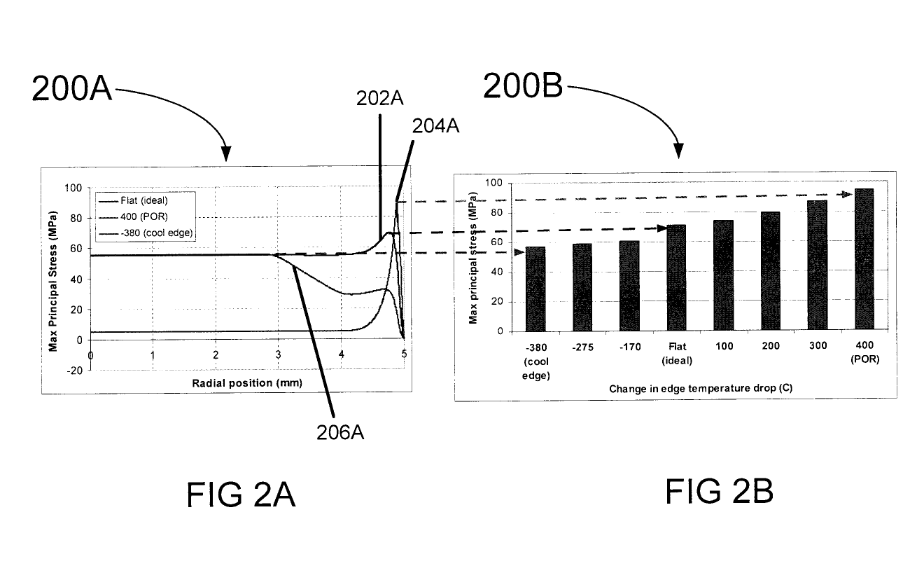

FIG. 2A illustrates a graph 200A according to some embodiments. Graph 200A illustrates a plot showing a maximum principal stress (for example, calculated using finite element analysis) as a function of the radius of the outer 5 mm of a wafer. Graph 200A illustrates three cases, including an ideal temperature distribution 202A where the temperature rise is the same at all radial positions, a case 204A where the temperature rise at the wafer edge is the highest, and a case 206A where the edge temperature is less than the center (this case 206A corresponds to a case, for example, resulting from an edge cooling and/or shadowing device). It is noted that the interior stresses of these three cases cannot be directly compared since they have been plotted at different depths, where the maximum principal stress occurs in the respective cases.

FIG. 2B illustrates a bar graph 200B which shows maximum principal stress for different temperature distributions for the entire wafer. A maximum stress is plotted vs. a change in edge temperature drop. It can be seen that if the change in edge temperature drop is positive (bars to the right of “Flat (ideal)” case), the maximum principal stress in the wafer is higher. The bar at the right-side extreme corresponds to a case that, having received radiation from the top and the side, results in an edge temperature drop change of +400C, and consequently, in the increase in maximum principal stress compared to the Flat (ideal) case. Similarly, if the change in edge temperature drop is negative (i.e., edge is cooler than the interior), the maximum principal stress is reduced (bars to the left of the “Flat (ideal)” case). The bar to the left-side extreme corresponds to the case where the edge might be deliberately cooled to result in a change in the edge temperature drop of −380C. The dashed lines (connecting FIG. 2A and FIG. 2B) simply show the correspondence between the two graphs: the maximum from the curve in FIG. 2A is taken and plotted in FIG. 2B. For example, the dashed line from 202A shows that the maximum from the Flat (ideal) curve in FIG. 2A (i.e. 202A), which reads approximately 70 MPa is taken and plotted as a bar in FIG. 2B for the same case (i.e, Flat (ideal)). Similarly, the maximum from 204A (approx: 95 MPa) is connected by the dashed line to the bar under 400 (POR) in FIG. 2B. Further, the maximum from 206A (approx 55 MPa) is connected by the dashed line to the bar under −380 (cool edge).

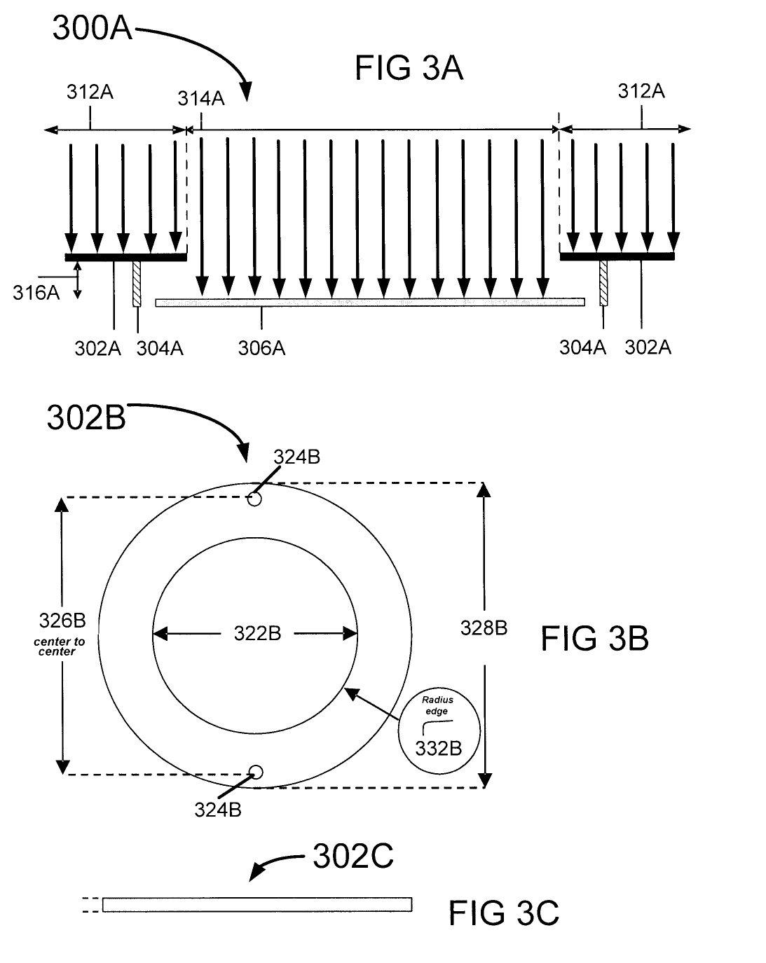

FIG. 3A illustrates an arrangement 300A according to some embodiments. Arrangement 300A includes a shadow ring 302A, a shadow ring support 304A, and a wafer 306A. The arrangement of the shadow ring 302A and shadow ring support 304A relative to the wafer 306A provide a way to cool an edge portion of the wafer 306A and/or reduce peak stress on the wafer 306A during a millisecond anneal (or flash anneal) process of fabrication of the wafer 306A. A light source (not shown) provides radiation illustrated by the arrows in FIG. 3A. The shadow ring 302A and/or the shadow ring support 304A ensure that the light (radiation) of the arrows does not extend downward to the wafer 306A in an area 312A of the shadow ring 302A (for example, no radiation extends below shadow ring 302A in FIG. 3A) while the light (radiation) of the arrows does extend downward to the wafer 306A in an area 314A where the shadow ring is open in the center. In some embodiments the distance (height) from the plane of the shadow ring 302A to the wafer (as shown by a vertical double arrow 316A in FIG. 3A) is as small as possible. In some embodiments the distance of arrow 316A is 1 mm. In some embodiments, the distance of arrow 316A is 2 mm. In some embodiments the edges of wafer 306A are maintained to be cooler due to the arrangement of the shadow ring 302A and/or shadow ring support 304A.

FIG. 3A illustrates light vectors coming straight down toward the wafer 306A and the shadow ring 302A. However, it is noted that in practical applications the light vectors do not all come straight down as illustrated in FIG. 3A. In some embodiments such as that shown in FIG. 3A, the shadow ring 302A does not entirely cover over the wafer 306A. However, the shadow ring 302A does shadow the wafer 306A by, for example, shadowing oblique lighting from the side. Although such oblique lighting is not specifically illustrated in FIG. 3A, the shadow ring 302A does shadow other lighting than merely light that comes straight down from the top of FIG. 3A (for example, oblique lighting from the side or other lighting and/or radiation, etc. In some embodiments there are different solutions. For example, in some embodiments shadowing may be performed by actually covering the edge of the wafer (for example, as illustrated in FIG. 3A). In some embodiments shadowing involves shadowing of oblique lighting (for example, in some embodiments, where the edge of the wafer is not covered by the shadow ring but where there is a gap between the outer edge of the wafer and the inner edge of the shadow ring, for example.

FIG. 3B illustrates a shadow ring 302B in a top view according to some embodiments. In some embodiments shadow ring 302B is open in the middle as shown by 322B. In some embodiments the diameter of the open section 322B is approximately 302 mm, in some embodiments the diameter of the open section 322B is approximately 304 mm, and in some embodiments the diameter of the open section 322B is approximately 306 mm. In some embodiments shadow ring 302B includes two pinholes 324B used to couple the shadow ring to a tool. It is noted that pinholes 324B are not necessary in all embodiments and/or a different arrangement of pinholes and/or a different way to couple the shadow ring to a tool can be used according to some embodiments. In some embodiments a measurement 326B between the center of the two pinholes 324B is approximately 397 mm from center to center. In some embodiments a diameter of the pinholes 324B is approximately 5 mm. In some embodiments the diameter 328B of the shadow ring 302B is approximately 408 mm. In some embodiments a radius edge 332B of the shadow ring 302B is 3 mm.

FIG. 3C illustrates a side view of a shadow ring 302C according to some embodiments. According to some embodiments a diameter of shadow ring 302C is similar to a diameter of shadow ring 302B. In some embodiments shadow ring 302B and shadow ring 302C have the same dimensions. In some embodiments, a depth of approximately 4 mm.

While specific measurements of shadow ring 302B and 302C have been described herein in an implementation in which a 300 mm in diameter wafer is being shadowed, it is acknowledged that any size wafer can be shadowed in some embodiments, and/or other measurements may be used in some embodiments.

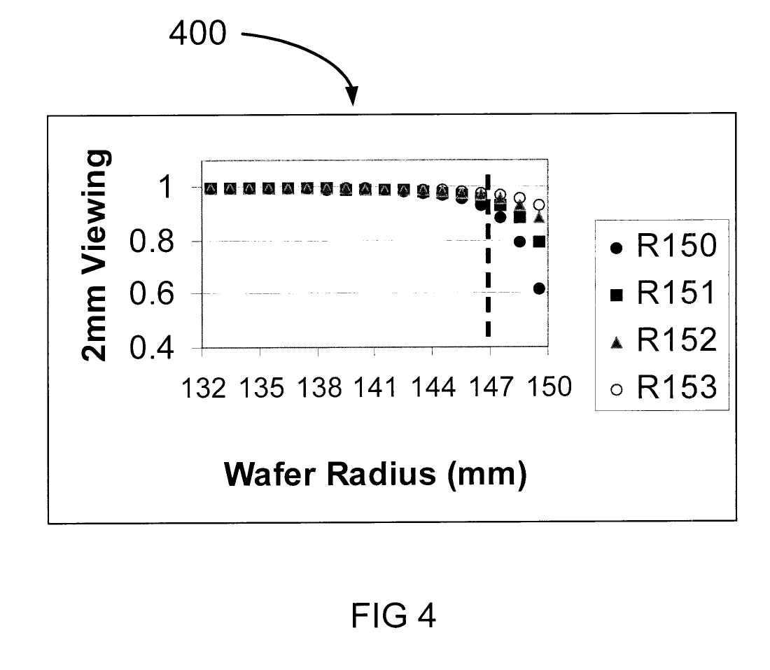

FIG. 4 illustrates a graph 400 according to some embodiments. Graph 400 illustrates the fraction of a light source seen from a point on a wafer. The parameters R150, R151, R152, and R153 in some embodiments correspond to the radius (in mm) of a shadowing device (for example, shadow ring), and a height of the shadow ring from the wafer is given as approximately 2 mm in some embodiments. The x axis in FIG. 4 is a radial position on the wafer in mm. FIG. 4 illustrates that as the ring diameter is reduced the shadowing extends further in from the edge of the wafer.

Although some embodiments have been described herein as being related to a shadow ring, according to some embodiments these particular implementations may not be required. In some embodiments any type of cooling of an outer portion, edge, and/or corner of a wafer may be implemented without requiring a shadow ring as described herein. For example, in some embodiments an outer portion, edge, and/or corner of a wafer may be implemented using liquid cooling (for example, in some embodiments, using water cooling).

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A method comprising:
providing radiation incident on a wafer to perform an annealing process; and
cooling the wafer at an edge portion to reduce temperature and stress on the wafer.

2. The method of claim 1, wherein the cooling is performed using a shadow ring to block radiation near the edge portion of the wafer.

3. The method of claim 2, wherein the shadow ring includes an open center and a solid ring at an edge.

4. The method of claim 3, wherein a diameter of the open center of the shadow ring is approximately the same diameter as the wafer.

5. The method of claim 3, wherein a diameter of the open center of the shadow ring is slightly larger than a diameter of the wafer.

6. The method of claim 3, wherein a diameter of the open center of the shadow ring is slightly smaller than a diameter of the wafer

7. The method of claim 1, wherein the stress on the wafer occurs at the edge portion of the wafer.

8. The method of claim 1, wherein the cooling of the wafer at the edge portion is performed using liquid cooling.

9. A wafer fabricated according to the following process:
providing radiation incident on the wafer to perform an annealing process; and
cooling the wafer at an edge portion to reduce temperature and stress on the wafer.

10. The wafer of claim 9, wherein the cooling is performed using a shadow ring to block radiation near the edge portion of the wafer.

11. The wafer of claim 10, wherein the shadow ring includes an open center and a solid ring at an edge.

12. The wafer of claim 11, wherein a diameter of the open center of the shadow ring is approximately the same diameter as the wafer.

13. The wafer of claim 11, wherein a diameter of the open center of the shadow ring is slightly larger than a diameter of the wafer.

14. The wafer of claim 11, wherein a diameter of the open center of the shadow ring is slightly smaller than a diameter of the wafer.

15. The wafer of claim 9, wherein the stress on the wafer occurs at the edge portion of the wafer.

16. The wafer of claim 9, wherein the cooling of the wafer at the edge portion is performed using liquid cooling.

17. A shadow ring comprising:
an open center; and
a solid ring at an edge portion to cool an edge portion of a wafer by blocking radiation provided during an annealing process of fabrication of the wafer so that temperature and stress occurring on the wafer is reduced.

18. The shadow ring of claim 17, wherein a diameter of the open center of the shadow ring is approximately the same diameter as the wafer.

19. The shadow ring of claim 17, wherein a diameter of the open center of the shadow ring is slightly larger than a diameter of the wafer.

20. The shadow ring of claim 17, wherein a diameter of the open center of the shadow ring is slightly smaller than a diameter of the wafer.

21. The shadow ring of claim 17, the shadow ring further comprising at least one pinhole to couple the shadow ring to a tool.
